(19) United States
(12) Patent Application Publication
(10) Pub. No.: US 2017/0193945 A1
(43) Pub. Date: Jul. 6, 2017

(54) SHIFT REGISTER UNIT, GATE DRIVING CIRCUIT AND DISPLAY DEVICE

(71) Applicants: Boe Technology Group Co., Ltd., Beijing (CN); Hefei Boe Optoelectronics Technology Co., Ltd., Anhui (CN)

(72) Inventor: Silin Feng, Beijing (CN)

(21) Appl. No.: 15/107,846

(22) PCT Filed: Jan. 13, 2016
(86) PCT No.: PCT/CN2016/070799

§ 371 Date: Jun. 23, 2016

(30) Foreign Application Priority Data
Jul. 20, 2015 (CN) 201510424670.0

(51) Int. Cl. G09G 3/36; G11C 19/18

(52) U.S. Cl. CPC G09G 3/3677; G11C 19/184; G09G 2310/0286; G09G 2300/0809; G09G 2310/061

(57) ABSTRACT

The present disclosure relates to the field of display technologies, and specifically to a shift register unit, a gate driving circuit comprising the shift register unit and a display device comprising the gate driving circuit. In accordance with an aspect of the present disclosure, a shift register unit is provided, which comprises a set module, a pull-down module, a pull-down control module, a reset module and an output module, wherein the pull-down module is only configured with two transistors to provide discharge channels via the first node and the output terminal, respectively.

### FIELD

The present disclosure relates to the field of display technologies, and specifically to a shift register unit, a gate driving circuit comprising the shift register unit and a display device comprising the gate driving circuit.

### BACKGROUND

In a typical active matrix liquid crystal display, each pixel has a thin film transistor (TFT), a gate of which is connected to a scan line in the horizontal direction, a drain of which is connected to a data line in the vertical direction, and a source of which is connected to a pixel electrode. When a certain scan line in the horizontal direction is applied with a sufficient positive voltage, all the TFTs on this line would be turned on. At that time, the pixel electrode of this line would be connected to the data line in the vertical direction. A video signal is written into the pixel. The effect of controlling the color can be achieved by controlling different transmittances of the liquid crystal.

Pixels in a display panel are generally driven using an external driving chip to display a picture. However, in order to reduce the number of elements and decrease the manufacture cost, at present the technique of manufacturing a driving circuit structure directly on the display panel is already utilized, for example, Gate Driver on Array (GOA) technique. In the GOA technique, a gate driving circuit is directly manufactured on the array substrate in place of the external driving chip. Since the gate driving circuit can be directly formed around the panel, the integration level of the TFT-LCD panel is improved, the process steps are reduced, and the manufacture cost is decreased.

FIG. 1 is a schematic diagram of a shift register unit in the prior art GOA circuit. As shown in FIG. 1, the shift register unit 100 comprises a set module 110, a pull-down module 120, a pull-down control module 130, a reset module 140 and an output module 150. The working principle of the GOA circuit is briefly described below with reference to FIG. 1.

When the input terminal INPUT is applied with a high level signal, and the first control signal input terminal CLK1 and the second control signal input terminal CLK2 are applied with a low level signal and a high level signal, respectively, the thin film transistor M1′ in the set module 110 is in turn-on state such that the pull-up node PU is at high potential, thus the thin film transistor M6′ in the pull-down control module 130 and the thin film transistor M3′ in the output module 150 are both in turn-on state. At that time, the input signal precharges the capacitor C1′ in the input module 150 via the pull-up node PU. Subsequently, the input terminal INPUT and the second control signal terminal CLK2 are applied with a low level signal while the first control signal terminal CLK1 is applied with a high level signal, such that the thin film transistor M1′ in the set module 110 and the thin film transistor M5′ in the pull-down control module 130 are in turn-off state, the pull-up node PU still maintains high potential, and the thin film transistor M3′ in the output module 150 is still in turn-on state. At that time, the output terminal OUTPUT would output a stable high level signal. Then, the input terminal INPUT and the first control signal terminal CLK1 are applied with a low level signal, and the second control signal terminal CLK2 and the reset signal terminal RESET are applied with a high level signal. At that time, the thin film transistor M2′ in the reset module 140 and the thin film transistor M4′ in the pull-down module 120 are in turn-on state, the capacitor C1 discharges via the output terminal OUTPUT and the thin film transistor M4′, and the pull-up node PU and the output terminal OUTPUT are at low potential. Finally, the input terminal INPUT, the second control signal terminal CLK2 and the reset signal terminal RESET are applied with a low level signal and the first control signal terminal CLK1 is applied with a high level signal, such that the pull-down node PD is at low potential, and the thin film transistors M2′ and M4′ are in turn-off state.

In the above shift register unit, when the input terminal INPUT and the first control signal terminal CLK1 are at low potential and the second control signal terminal CLK2 are at high potential, the high potential of the pull-down node PD enables the thin film transistors M8′ and M9′ to be turned on to provide discharge channels for the capacitor C1, but the thin film transistors M2′ and M4′ are in idle state at that time. Likewise, when the reset signal terminal RESET is at high potential, the thin film transistors M2′ and M4′ provide discharge channels for the capacitor C1 while the thin film transistors M8′ and M9′ are in idle state. It can be seen that the thin film transistors in the above circuit are not efficiently utilized, which not only results in waste of resources but also increases the area of the GOA circuit.

### SUMMARY

The present disclosure provides a shift register unit, a gate driving circuit and a display device, which has the advantage of reducing the area of the GOA circuit without changing the original working mode and function of the shift register unit.

In accordance with an aspect of the present disclosure, a shift register unit is provided, which comprises a set module, a pull-down module, a pull-down control module, a reset module and an output module. The output module comprises a capacitor coupled between a first node and an output terminal, the set module is coupled to the first node so as to charge the capacitor in response to a set signal, the pull-down module is coupled to the first node and the output terminal to provide discharge channels, the pull-down control module and the reset module are coupled to controlled ends of the pull-down module via a second node so as to control level states of the first node and the output terminal by means of the pull-down module,

wherein the pull-down module is only configured with two transistors to provide discharge channels via the first node and the output terminal, respectively.

In the above shift register unit, the purpose of reducing the area occupied by the gate driving circuit is achieved by reducing the number of transistors as discharge channels, which facilitates the design of a narrow-frame liquid crystal display. Furthermore, since the working principle and function of the shift register unit are still kept unchanged, there is no need to adaptively modify other circuits, thereby decreasing the development and manufacture cost significantly.

In accordance with embodiments of the present disclosure, in the above shift register unit, the reset module comprises a transistor arranged between the second node and a reset signal terminal as a unidirectional conducting switch to isolate impact of the level signal at the second node on the reset signal terminal. In said shift register unit, the arrangement of the unidirectional conducting switch may effectively eliminate abnormal bright spots present on the display screen.

In accordance with embodiments of the present disclosure, in the above shift register unit, the set module comprises a first transistor, the source and the gate thereof are connected to an input signal terminal, and the drain thereof is connected to the first node.

The pull-down module comprises a second transistor and a fourth transistor. The source of the second transistor is connected to the drain of the first transistor, and the source of the fourth transistor is connected to the output terminal. The drains of the second transistor and the fourth transistor are both connected to a reference voltage terminal, and the gates thereof are both connected to the second node.

The pull-down control module comprises a fifth transistor and a sixth transistor. The source and the gate of the fifth transistor are connected to a second control signal terminal, and the drain of the fifth transistor is connected to the second node. The source of the sixth transistor is connected to the second node, the drain of the sixth transistor is connected to the reference voltage terminal, and the gate of the sixth transistor is connected to the first node.

The output module further comprises a third transistor. The source thereof is connected to a first signal control terminal, the drain thereof is connected to the output terminal, and the gate thereof is connected to the first node.

The reset module comprises a seventh transistor. The source and the gate thereof are connected to the reset signal terminal, and the drain thereof is connected to the second node.

In accordance with embodiments of the present disclosure, in the above shift register unit, the width to length ratio of the fifth transistor is larger than that of the sixth transistor. In said shift register unit, designing the width to length ratios of the fifth and sixth transistors can ensure the stability of the output signal at the output terminal of the shift register unit.

In accordance with embodiments of the present disclosure, in the above shift register unit, the first to seventh transistors are thin film transistors.

In accordance with another aspect of the present disclosure, a gate driving circuit is provided, which comprises n cascaded shift register units as described above, the n being an integral greater than 1,

wherein first control signal terminals and second control signal terminals of the n shift register units are connected together respectively, and an output terminal of a shift register unit is coupled to the reset signal terminal of the previous-stage shift register unit and an input terminal of the next-stage shift register unit so as to use an output signal of the shift register unit as a set signal for the previous-stage shift register unit and as a reset signal for the next-stage shift register unit.

In accordance with another aspect of the present disclosure, a display device is provided, which comprises the above gate driving circuit.

### BRIEF DESCRIPTION OF DRAWINGS

The above and/or other aspects and advantages of the present disclosure will become clearer and easier to understand by virtue of the description of respective aspects below with reference to the drawings. The same or similar units in the drawings are denoted with the same reference numbers. The drawings include:

FIG. 1 is a schematic diagram of a shift register unit in the prior art GOA circuit.

FIG. 2 is a block diagram of a shift register unit according to an embodiment of the present disclosure.

FIG. 3 is a schematic diagram of a circuit for implementing the shift register unit as shown in FIG. 2.

FIG. 4 is a signal timing diagram of the shift register unit as shown in FIG. 3.

FIG. 5 is a schematic diagram of a gate driving circuit according to an embodiment of the present disclosure.

### DETAILED DESCRIPTION

The present disclosure is set forth below more comprehensively with reference to the drawings in which schematic embodiments of the present disclosure are illustrated. However, the present disclosure may be implemented in different forms, but should not be interpreted as being only limited to the embodiments provided herein. The provided embodiments intend to reveal the present disclosure comprehensively and completely, so as to convey the protection scope of the present disclosure to those skilled in the art in a comprehensive manner.

In the present description, “coupling” should be understood as the circumstance of directly transmitting electric energy or electric signals between two units, or the circumstance of indirectly transmitting electric energy or electric signals via one or more third units.

The expressions such as “comprise” and “include” indicate the circumstance that the technical solutions of the present disclosure do not exclude having other units and steps not directly or explicitly expressed besides having the units and steps that have been directly and explicitly expressed in the description and Claims.

The expressions such as “first” and “second” do not represent the order of units in terms of time, space, size, etc, but are only used for differentiating between respective units.

The embodiments for implementing the present disclosure are described below by virtue of the drawings.

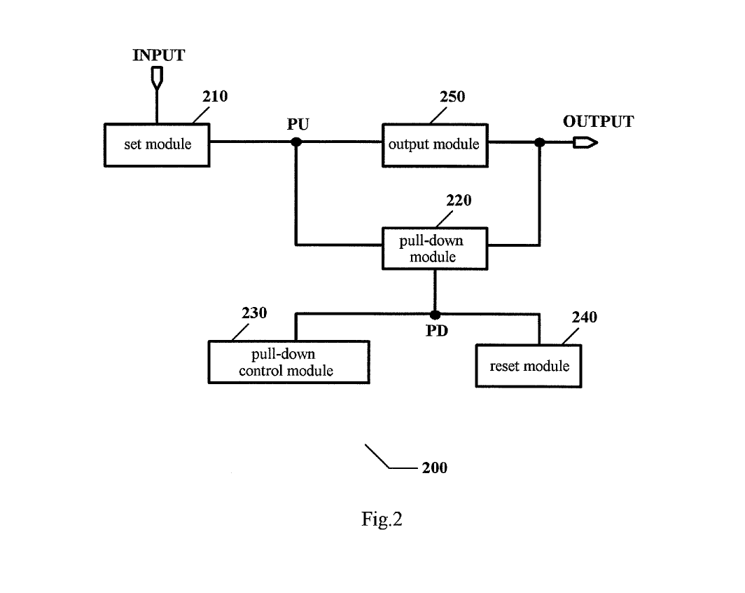

FIG. 2 is a block diagram of a shift register unit according to an embodiment of the present disclosure. A shift register unit 200 as shown in FIG. 2 comprises a set module 210, a pull-down module 220, a pull-down control module 230, a reset module 240 and an output module 250. The set module 210 is coupled to the output module via a first node or a pull-up node PU, which is configured to provide a set signal at the first node PU in response to an input signal for executing a set operation. In the present embodiment, the output module 250 comprises a capacitor coupled between the first node PU and the output terminal OUTPUT. The function of the shift register 200 is carried out by charging the capacitor via the first node PU and discharging the capacitor via the first node PU and the output terminal OUTPUT. The pull-down module 220 is coupled to the first node PU and the output terminal OUTPUT, thereby providing discharge channels for the capacitor. The pull-down control module 230 and the reset module 240 are coupled to controlled ends of the pull-down module 220 via a second node or a pull-down node PD, thereby controlling the level states at the first node PU and the output terminal OUTPUT by means of the pull-down module.

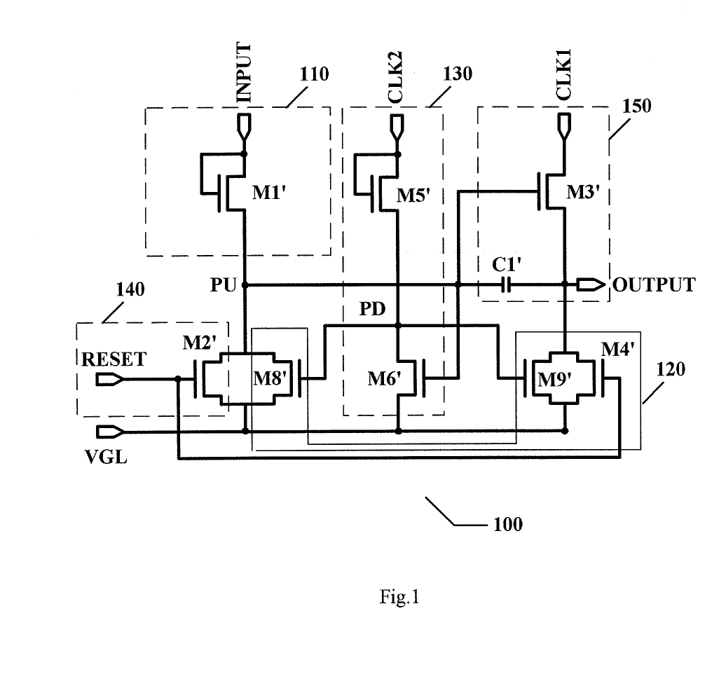

Different from the prior art shift register unit as shown in FIG. 1, in the present embodiment, two transistors respectively coupled to the first node and the output terminal are configured only in the pull-down module 220 for the capacitor as discharge channels, as a result, the number of the used transistors is reduced.

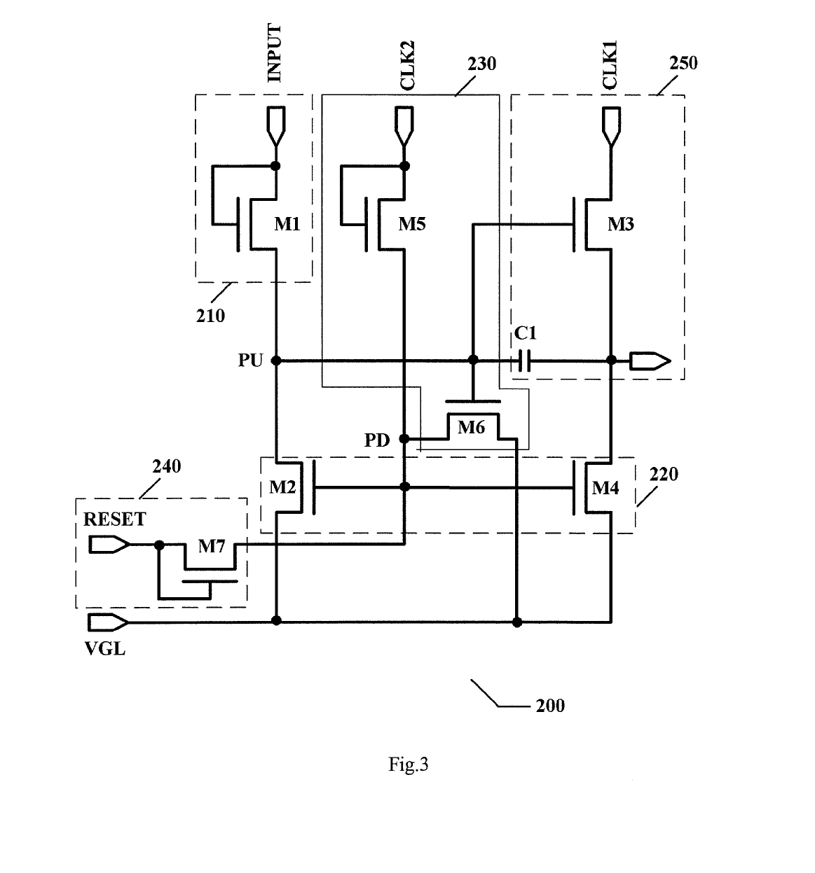

FIG. 3 is a schematic diagram of a circuit for implementing the shift register unit as shown in FIG. 2. A shift register unit 200 as shown in FIG. 3 comprises a set module 210, a pull-down module 220, a pull-down control module 230, a reset module 240 and an output module 250. The structure of each module is further described below.

Referring to FIG. 3, the output module 250 comprises a third transistor M3 and a capacitor C1. The source of the third transistor M3 is connected to a first signal control terminal CLK1, and the drain and the gate thereof are connected to two terminals of the capacitor C1 (i.e. connected to the output terminal OUTPUT and the first node PU).

As shown in FIG. 3, the set module 210 comprises a first transistor M1. The source and the gate of the first transistor are both connected to an input terminal INPUT, and the drain thereof is connected to the first node PU, thus the first node can be applied with a high level or low level signal by means of an input signal.

As shown in FIG. 3, the pull-down module 220 comprises a second transistor M2 and a fourth transistor M4 which are connected to two terminals of the capacitor C1 respectively as discharge channels of the capacitor C1 (i.e. connected to the first node PU and the output terminal OUTPUT). Specifically, the source of the second transistor M2 and the drain of the first transistor M1 in the set module 210 are both connected to the first node PU, and the source of the fourth transistor M4 is connected to the output terminal OUTPUT. Furthermore, the drains of the second transistor M2 and the fourth transistors M4 are both connected to a reference voltage terminal VGL, and the gates thereof are both connected to the second node PD. In the present embodiment, the gates of the second transistor M2 and the fourth transistor M4 can be regarded as controlled ends of the pull-down module 210.

Referring to FIG. 3, the pull-down control module 230 comprises a fifth transistor M5 and a sixth transistor M6, wherein the source and the gate of the fifth transistor M5 are connected to a second control signal terminal CLK2, and the drain of the fifth transistor M5 is connected to the second node PD. The source of the sixth transistor M6 is also connected to the second PD, the drain of the sixth transistor M6 is connected to the reference voltage terminal VGL, and the gate of the sixth transistor M6 is connected to the first node PU.

The reset module 240 provides a reset signal to the controlled ends of the pull-down module 220 via the second node PD. Preferably, in the present embodiment, the reset module 240 comprises a seventh transistor M7. The source and the gate of the seventh transistor M7 are connected to a reset signal terminal RESET, and the drain thereof is connected to the second node PD, thereby constituting a unidirectional conducting switch between the second node PD and the reset signal terminal.

It is to be noted that in a gate driving circuit comprising multiple cascaded shift register units, if the reset signal terminal RESET is directly connected to the second node PD, when the reset signal terminal RESET is connected to the output terminal OUTPUT of the next-stage shift register unit, a row of abnormal bright spots would be present on the display screen due to the impact of the high potential of the second node PD. The arrangement of the above unidirectional conducting switch can effectively isolate the impact of the potential state of the second node on the reset signal terminal, thereby eliminating the abnormal bright spots. Specifically, when the transistor M7 is connected between the reset signal terminal RESET and the second node PD in the manner as shown in FIG. 3, the transistor M7 enters turn-on state only when the reset signal terminal RESET is applied with a high level signal. Therefore, the high potential of the second node PD would not produce impact on the reset signal terminal RESET.

In the present embodiment, the transistors M1 to M7 are thin film transistors, which may be N-type channel transistors and may also be P-type channel transistors.

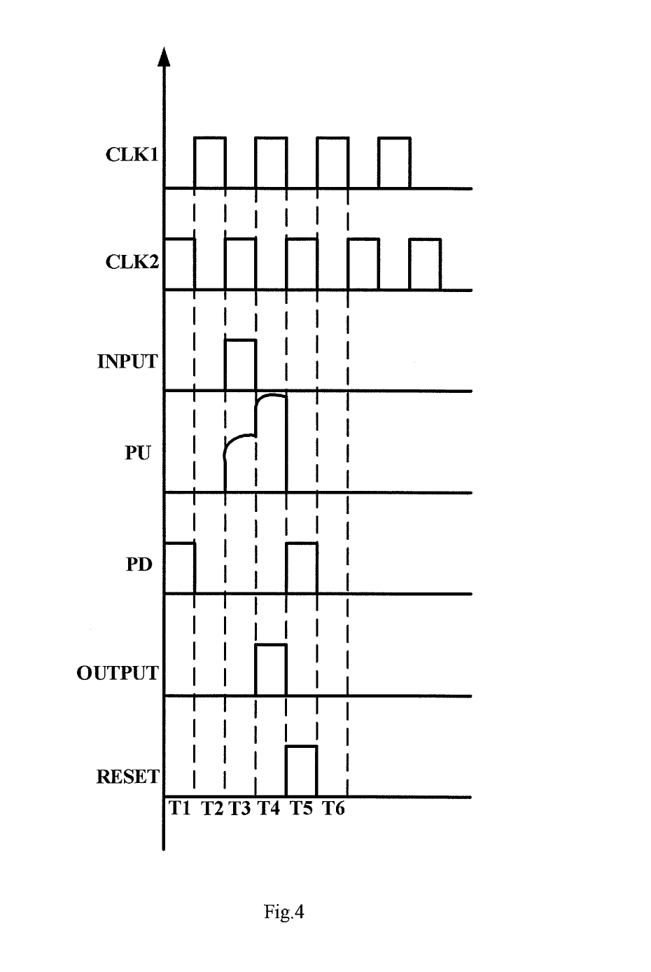

FIG. 4 is a signal timing diagram of the shift register as shown in FIG. 3. The working principle of the shift register unit according to the present embodiment is described below with reference to FIG. 4.

Referring to FIG. 4, the first clock input terminal CLK1 and the second clock input terminal CLK2 are applied with square wave signals with a duty cycle of 50%, and the duration of a high level and a low level corresponds to one clock signal interval. The working state of the shift register unit during respective intervals within one frame period is described below.

In a first clock signal interval T1 of the timing diagram as shown in FIG. 4, a low level signal is applied to the input terminal INPUT, the first clock input terminal CLK1 and the reset signal terminal RESET, and a high level signal is applied to the second clock input terminal CLK2. At this stage, the transistors M1, M3, M6 and M7 are in turn-off state, while the transistor M5 is in turn-on state, such that the first node PU and the output terminal OUTPUT are at low potential and the second node PD is at high potential. The high potential of the second node PD enables the transistors M2 and M4 to be in turn-on state, and consequently provides discharge channels for the first node PU and the output terminal OUTPUT so as to eliminate the noises at the first node PU and the output terminal OUTPUT. The transistor M3 with relatively large size causes a parasitic capacitance between the gate and the drain to be not negligible. Furthermore, when the first node PU is at low potential while the first control signal terminal CLK1 is at high potential, noises would also be induced at the first node PU. Therefore, the noise eliminating operation during the first clock signal interval is beneficial, especially for the above situation.

Subsequently, continue with a second clock signal interval T2. At that time, a high level signal is applied to the first clock input terminal CLK1, and a low level signal is applied to the input terminal INPUT, the second clock input terminal CLK2 and the reset signal terminal RESET. Consequently, the transistors M1, M5 are in turn-off state, the first node PU, the second node PD and the output terminal OUTPUT are all at low potential, and further the transistors M2, M3, M4 and M7 are all in turn-off state.

In a third clock signal interval T3, a high level signal is applied to the input terminal INPUT as a set signal, and a low level signal is applied to the first clock input terminal CLK1 and the reset signal terminal RESET while a high level signal is applied to the second clock input terminal CLK2. Consequently, the transistor M1 is in turn-on state, and the first node PU is pulled up to high potential to charge the capacitor C1. Meanwhile, the transistors M3 and M6 are in turn-on state such that the second node PD maintains low potential, and the transistors M2 and M4 are still in turn-off state. At that time, the output terminal OUTPUT is still at low potential.

In a fourth clock signal interval T4, at that time a high level signal is applied to the first clock input terminal CLK1, and a low level signal is applied to the input terminal INPUT, the second clock input terminal CLK2 and the reset signal terminal RESET. Consequently, the transistors M1 and M5 are in turn-off state while the transistor M3 is turn-on state. Since the second node PD maintains low potential, the transistor M2 is still in turn-off state, such that the high potential of the first node PU can be maintained. Meanwhile, a high level signal is applied to the first clock input terminal CLK1 and the transistor M3 is in turn-on state, thereby outputting the high level signal at the output terminal OUTPUT.

Preferably, the width to length ratio of the transistor M5 can be designed to be larger than that of the transistor M6 so as to make the resistance of the transistor M5 much larger than that of the transistor M6. The above design ensures that the second node PD maintains low potential within the fourth clock signal interval such that the transistors M2 and M4 are in turn-off state to ensure that a stable high level signal is output at the output terminal OUTPUT.

In a fifth clock signal interval T5, a high level signal is applied to the reset signal terminal RESET as a reset signal, and a high level signal is also applied to the second clock input terminal CLK2 while a low level signal is applied to the input terminal INPUT and the first clock input terminal CLK1, such that the transistors M1 and M3 are in turn-off state while the transistors M5 and M7 are in turn-on state. At that time, the second node PD converts to high potential such that the transistors M2 and M4 go into turn-on state to provide discharge channels respectively for the capacitor C1 and the output terminal OUTPUT, thereby causing the first node PU and the output terminal OUTPUT to convert to low potential. On the other hand, the first node PU at low potential enables the transistor M6 to be in turn-off state, which ensures that the second node PD maintains high potential.

In a sixth clock signal interval T6, at that time a high level signal is applied to the first clock input terminal CLK1, and a low level signal is applied to the input terminal INPUT, the second clock input terminal CLK2 and the reset signal terminal RESET. Consequently, the transistors M1, M5 and M7 are in turn-off state. At that time the first node PU and the second node PD are at low potential such that the transistors M2, M3, M4 and M6 go into turn-off state.

Subsequently, the input terminal INPUT, the first clock input terminal CLK1, the second clock input terminal CLK2 and the reset signal terminal RESET will alternately repeat the level states during the fifth and sixth clock signal intervals constantly until the next frame signal appears.

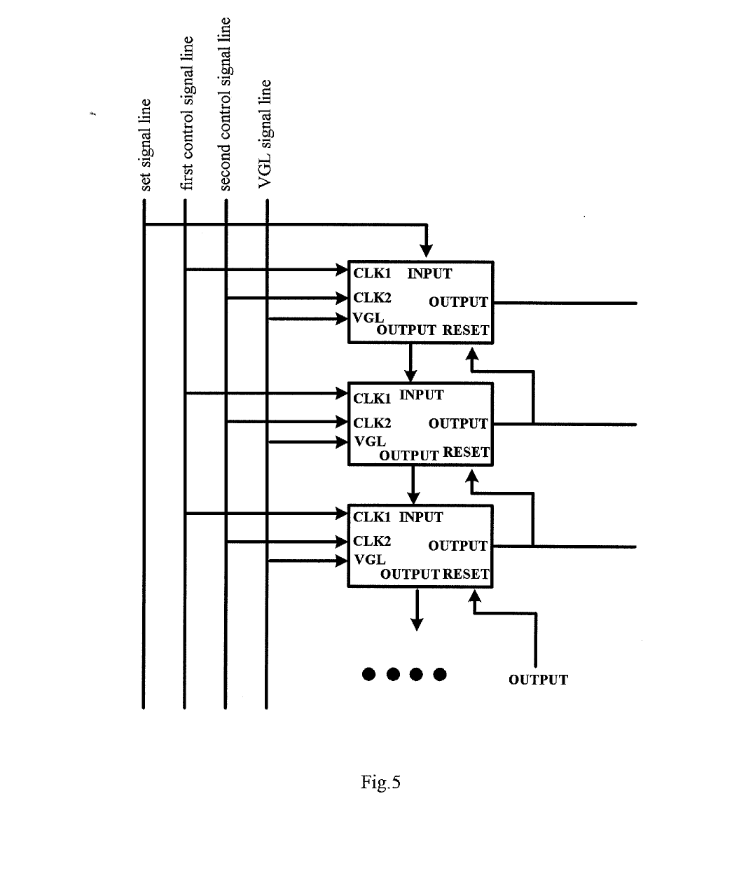

FIG. 5 is a schematic diagram of a gate driving circuit according to an embodiment of the present disclosure. The gate driving circuit as shown in FIG. 5 comprises a plurality of cascaded shift register units, wherein each shift register unit may be the shift register unit according to FIGS. 1 to 4 or its equivalent variation. In the present embodiment, the n cascaded shift register units are cascaded in the following manner: the first control signal terminals CLK1 of the respective shift register units are all connected to a first control signal line, the second control signal terminals CLK2 are all connected to a second control signal line, and the VGL terminals are all connected to a VGL line. Moreover, for one shift register unit, its output terminal OUTPUT is coupled to the reset signal terminal RESET of the previous-stage shift register unit and the input terminal INPUT of the next-stage shift register unit, so as to use the output signal thereof as a set signal for the previous-stage shift register unit and as a reset signal for the next-stage shift register unit. As regards the first shift register unit as cascaded, the input terminal INPUT thereof is connected to a set signal line to receive the set signal.

Although the respective illustrative embodiments are already illustrated and explained, those ordinarily skilled in the art should understand that various modifications can be made to these illustrative embodiments in terms of forms and details, without departing the spirit and scope of the concept of the present disclosure as defined in the enclosed Claims.

1. A shift register unit comprising a set module, a pull-down module, a pull-down control module, a reset module and an output module, wherein the output module comprises a capacitor coupled between a first node and an output terminal, the set module is coupled to the first node so as to charge the capacitor in response to a set signal, the pull-down module is coupled to the first node and the output terminal to provide discharge channels, the pull-down control module and the reset module are coupled to controlled ends of the pull-down module via a second node so as to control level states of the first node and the output terminal by means of the pull-down module,
wherein the pull-down module is only configured with two transistors to provide discharge channels via the first node and the output terminal, respectively.

2. The shift register unit according to claim 1, wherein the reset module comprises a transistor arranged between the second node and a reset signal terminal as a unidirectional conducting switch to isolate impact of a level signal at the second node on the reset signal terminal.

3. The shift register unit according to claim 1, wherein
the set module comprises a first transistor, a source and a gate thereof being connected to an input signal terminal, a drain thereof being connected to the first node;
the pull-down module comprises a second transistor and a fourth transistor, a source of the second transistor being connected to the drain of the first transistor, a source of the fourth transistor being connected to the output terminal, drains of the second transistor and the fourth transistor being both connected to a reference voltage terminal, gates of the second transistor and the fourth transistor being both connected to the second node;
the pull-down control module comprises a fifth transistor and a sixth transistor, a source and a gate of the fifth transistor being connected to a second control signal terminal, a drain of the fifth transistor being connected to the second node, a source of the sixth transistor being connected to the second node, a drain of the sixth transistor being connected to the reference voltage terminal, a gate of the sixth transistor being connected to the first node;
the output module further comprises a third transistor, a source of the third transistor being connected to a first signal control terminal, a drain of the third transistor being connected to the output terminal, a gate of the third transistor being connected to the first node;
the reset module comprises a seventh transistor, a source and a gate of the seventh transistor being connected to the reset signal terminal, a drain of the seventh transistor being connected to the second node.

4. The shift register unit according to claim 3, wherein the width to length ratio of the fifth transistor is larger than that of the sixth transistor.

5. The shift register unit according to claim 1, wherein the first to seventh transistors are thin film transistors.

6. A gate driving circuit, comprising n cascaded shift register units the n being an integral greater than 1,
wherein, each shift register unit comprises a set module, a pull-down module, a pull-down control module, a reset module and an output module, wherein the output module comprises a capacitor coupled between a first node and an output terminal, the set module is coupled to the first node so as to charge the capacitor in response to a set signal, the pull-down module is coupled to the first node and the output terminal to provide discharge channels, the pull-down control module and the reset module are coupled to controlled ends of the pull-down module via a second node so as to control level states of the first node and the output terminal by means of the pull-down module,
wherein the pull-down module is only configured with two transistors to provide discharge channels via the first node and the output terminal, respectively
wherein first control signal terminals and second control signal terminals of n shift register units are connected together respectively, and an output terminal of a shift register unit is coupled to a reset signal terminal of the previous-stage shift register unit and an input terminal of the next-stage shift register unit so as to use an output signal of the shift register unit as a set signal for the previous-stage shift register unit and as a reset signal for the next-stage shift register unit.

7. The shift register unit according to claim 2, wherein the first to seventh transistors are thin film transistors.

8. The shift register unit according to claim 3, wherein the first to seventh transistors are thin film transistors.

9. The shift register unit according to claim 4, wherein the first to seventh transistors are thin film transistors.

10. The gate driving circuit according to claim 6, wherein the reset module comprises a transistor arranged between the second node and a reset signal terminal as a unidirectional conducting switch to isolate impact of a level signal at the second node on the reset signal terminal.

11. The gate driving circuit according to claim 6, wherein
the set module comprises a first transistor, a source and a gate thereof being connected to an input signal terminal, a drain thereof being connected to the first node;
the pull-down module comprises a second transistor and a fourth transistor, a source of the second transistor being connected to the drain of the first transistor, a source of the fourth transistor being connected to the output terminal, drains of the second transistor and the fourth transistor being both connected to a reference voltage terminal, gates of the second transistor and the fourth transistor being both connected to the second node;
the pull-down control module comprises a fifth transistor and a sixth transistor, a source and a gate of the fifth transistor being connected to a second control signal terminal, a drain of the fifth transistor being connected to the second node, a source of the sixth transistor being connected to the second node, a drain of the sixth transistor being connected to the reference voltage terminal, a gate of the sixth transistor being connected to the first node;
the output module further comprises a third transistor, a source of the third transistor being connected to a first signal control terminal, a drain of the third transistor being connected to the output terminal, a gate of the third transistor being connected to the first node;
the reset module comprises a seventh transistor, a source and a gate of the seventh transistor being connected to the reset signal terminal, a drain of the seventh transistor being connected to the second node.

12. The gate driving circuit according to claim 11, wherein the width to length ratio of the fifth transistor is larger than that of the sixth transistor.

13. The gate driving circuit according to claim 6, wherein the first to seventh transistors are thin film transistors.

14. The gate driving circuit according to claim 10, wherein the first to seventh transistors are thin film transistors.

15. The gate driving circuit according to claim 11, wherein the first to seventh transistors are thin film transistors.

16. The gate driving circuit according to claim 12, wherein the first to seventh transistors are thin film transistors.

17. A display device comprising a gate driving circuit, the gate driving circuit comprising n cascaded shift register units, the n being an integral greater than 1,
wherein, each shift register unit comprises a set module, a pull-down module, a pull-down control module, a reset module and an output module, wherein the output module comprises a capacitor coupled between a first node and an output terminal, the set module is coupled to the first node so as to charge the capacitor in response to a set signal, the pull-down module is coupled to the first node and the output terminal to provide discharge channels, the pull-down control module and the reset module are coupled to controlled ends of the pull-down module via a second node so as to control level states of the first node and the output terminal by means of the pull-down module,
wherein the pull-down module is only configured with two transistors to provide discharge channels via the first node and the output terminal, respectively
wherein first control signal terminals and second control signal terminals of n shift register units are connected together respectively, and an output terminal of a shift register unit is coupled to a reset signal terminal of the previous-stage shift register unit and an input terminal of the next-stage shift register unit so as to use an output signal of the shift register unit as a set signal for the previous-stage shift register unit and as a reset signal for the next-stage shift register unit.

18. The display device according to claim 17, wherein the reset module comprises a transistor arranged between the second node and a reset signal terminal as a unidirectional conducting switch to isolate impact of a level signal at the second node on the reset signal terminal.

19. The display device according to claim 17, wherein
the set module comprises a first transistor, a source and a gate thereof being connected to an input signal terminal, a drain thereof being connected to the first node;
the pull-down module comprises a second transistor and a fourth transistor, a source of the second transistor being connected to the drain of the first transistor, a source of the fourth transistor being connected to the output terminal, drains of the second transistor and the fourth transistor being both connected to a reference voltage terminal, gates of the second transistor and the fourth transistor being both connected to the second node;
the pull-down control module comprises a fifth transistor and a sixth transistor, a source and a gate of the fifth transistor being connected to a second control signal terminal, a drain of the fifth transistor being connected to the second node, a source of the sixth transistor being connected to the second node, a drain of the sixth transistor being connected to the reference voltage terminal, a gate of the sixth transistor being connected to the first node;
the output module further comprises a third transistor, a source of the third transistor being connected to a first signal control terminal, a drain of the third transistor being connected to the output terminal, a gate of the third transistor being connected to the first node;
the reset module comprises a seventh transistor, a source and a gate of the seventh transistor being connected to the reset signal terminal, a drain of the seventh transistor being connected to the second node.

20. The display device according to claim 19, wherein the width to length ratio of the fifth transistor is larger than that of the sixth transistor.
